(19) United States
(12) Patent Application Publication
(10) Pub. No.: US 2010/0224864 A1
(43) Pub. Date: Sep. 9, 2010

(54) Organic light emitting diode and method for manufacturing the same

(75) Inventors: Meng-Tan Chiang, Bade City (TW); Ping-Hsun Lu, Bade City (TW); Cheng-Hsiang Chuang, Bade City (TW); Tsung-Pei Tseng, Hsinchu City (TW); Shieh-Jun Wang, Taipei City (TW)

Correspondence Address: BACON & THOMAS, PLLC, 625 SLATERS LANE, FOURTH FLOOR, ALEXANDRIA, VA, 22314-1176, US

(73) Assignees: Yuan-Shin Materials Technology Corp., Taipei City (TW); Chung-shan Institute of Science and Technology. Armaments Bureau. M.N.D., Longtan Township (TW)

(21) Appl. No.: 12/591,283

(22) Filed: Nov. 16, 2009

(30) Foreign Application Priority Data
Mar. 4, 2009 (TW) 098106952

(51) Int. Cl. H01L 51/50; H01L 51/56

(52) U.S. Cl. 257/40; 438/29; 438/99; 257/E51.018

(57) ABSTRACT

An organic light emitting diode (OLED) and a method for manufacturing the same are disclosed, wherein the method comprises following steps: (a) providing a substrate having a first conductive layer; (b) providing a precursor and polymerizing the precursor by plasma to form a fluorocarbon polymer layer or a fluorocarbon copolymer layer on the first conductive layer of the substrate; (c) forming an organic light emitting structure on the fluorocarbon polymer layer or a fluorocarbon copolymer layer; and (d) forming a second conductive layer on the organic light emitting structure. The hole injection efficiency of the OLED can be improved by the method of the present invention. Hence, the current density of the OLED can be greatly increased.

### BACKGROUND OF THE INVENTION

1. Field of the Invention

The present invention relates to a light emitting diode and, more particularly, to an organic electroluminescence diode.

2. Description of Related Art

FIG. 1 shows a cross-sectional view of a conventional organic light emitting diode, which includes: a substrate 101; an anode 102 on the substrate 101; and an organic light emitting structure 107, including an organic hole transporting layer 103, an organic emissive layer 104 and an organic electron transporting layer 105 in sequence. In other words, the organic emissive layer 104 is disposed between the organic hole transporting layer 103 and the organic electron transporting layer 105. The main function of the organic emissive layer 104 is to limit or control the efficient combination between electrons and holes, resulting in emission. In addition, a cathode 106 is disposed on the organic electron transporting layer 105.

When a potential difference is applied between the anode 102 and the cathode 106, the anode is viewed as positive (with respect to the cathode), and electrons will be injected from the cathode to the organic electron transporting layer 105 and pass through the organic electron transporting layer 105 and the organic emissive layer 104. Meanwhile, holes will be injected from the anode into the organic hole transporting layer 103 and pass through the organic hole transporting layer 103. Finally, holes and electrons recombine at the junction between the organic hole transporting layer 103 and the organic emissive layer 104. When an electron drops from the conduction band back down to the valence band to combine with a hole, energy is released as light and light is emitted in a direction from the transparent anode and then the substrate to a viewer.

In the above-mentioned organic light emitting diode, the function of each organic layer is clarified and may be individually optimized. Thereby, the organic light emitting structure 107 can be designed to emit light with various colors and exhibit higher emission efficiency. Meanwhile, for carrier mobility, the organic electron transporting layer and the organic hole transporting layer can be suitably modified.

As known in the art, the application of a cathode with a low work function and an anode with a high work function can significantly reduce the driving voltage of the organic light emitting diode. Conventionally, the anode is made of conductive and transparent oxides. For example, Indium Tin Oxide (ITO) has been widely applied in the anode due to its transparency, excellent conductivity and high work function.

However, in the case that a light emitting structure is grown on ITO, generally, poor current-voltage characteristics and low operating stability are shown. In order to improve the issue, Vanslyke et al. (APL, VOL 69, 2160, 1996, Organic electroluminescent devices with improved stability) disclosed another organic light emitting diode with a multi-layered structure, as shown in FIG. 2. In such organic light emitting diode, similarly, the organic light emitting structure 107 includes an organic hole transporting layer 103, an organic emissive layer 104 and an organic electron transporting layer 105, and these layers have the above-mentioned desired functions. The organic light emitting diode shown in FIG. 2 is characterized in that an additional hole injection layer 210 is formed between the anode 102 and the organic hole transporting layer 103, and the material of the hole injection layer 210 is copper phthalocyanine (Cupc).

However, when the Cupc layer is disposed between the anode 102 and the organic hole transporting layer 103, the driving voltage substantially increases due to the hole injection energy barrier at the junction between the Cupc layer and the organic hole transporting layer 103 (such as NPB). Thereby, it is necessary to further enhance the hole injection efficiency of the organic light emitting diode and to improve the operating stability of the device.

### SUMMARY OF THE INVENTION

One object of the present invention is to provide an organic light emitting diode (OLED) that exhibits enhanced current density, increased brightness, reduced driving voltage and improved operating stability.

Another object of the present invention is to provide a method for manufacturing an organic light emitting diode to obtain the above-mentioned organic light emitting diode.

To achieve the object, the organic light emitting diode of the present invention includes: a substrate; a first conductive layer, disposed on a surface of the substrate; a fluorocarbon polymer layer or a fluorocarbon copolymer layer, disposed on the first conductive layer; an organic light emitting structure, disposed on the fluorocarbon polymer layer or the fluorocarbon copolymer layer; and a second conductive layer, disposed on the organic light emitting structure.

In the organic light emitting diode according to the present invention, the fluorocarbon polymer layer is not particularly limited. Preferably, a fluorizated poly xylylene layer is used.

In the organic light emitting diode according to the present invention, preferably, the fluorocarbon polymer layer or the fluorocarbon copolymer layer is represented by the following formula (I),

(—CF₂—C₆X₄—CF₂—)ₙ (I)

wherein, X is H or F, and n is 2 or an integer larger than 2.

In the organic light emitting diode according to the present invention, preferably, the thickness of the fluorocarbon polymer layer or the fluorocarbon copolymer layer ranges from 0.2 nm to 20 nm.

In the organic light emitting diode according to the present invention, preferably, the organic light emitting structure includes an organic hole transporting layer and an organic electron transporting layer, in which the organic hole transporting layer is formed on the fluorocarbon polymer layer or the fluorocarbon copolymer layer, and the second conductive layer is formed on the organic electron transporting layer.

Preferably, the above-mentioned organic light emitting diode may further include an organic emissive layer between the organic hole transporting layer and the organic electron transporting layer.

In the above-mentioned organic light emitting diode, the organic hole transporting layer is not particularly limited, and any conventional organic hole transporting layer can be employed in the present invention. Preferably, aromatic tertiary amine containing at least one trivalent nitrogen atom bonding to carbon atoms and at least one aromatic ring is used in the organic hole transporting layer. Preferably, the aromatic tertiary amine may be monoarylamine, diarylamine or triarylamine.

In the above-mentioned organic light emitting diode, the organic emissive layer is not particularly limited, and any conventional organic emissive layer can be employed in the present invention, including luminescence materials or fluorescent materials. Preferably, tri(8-quinolinolate-N1,08)-aluminum (Alq) is used in the organic emissive layer. More preferably, the organic emissive layer contains a host material and one or more kinds of fluorescent dyes as dopants. Herein, the emitting color of the organic light emitting diode can be modified by doping the host material with fluorescent dyes of various emission wavelengths.

In the above-mentioned organic light emitting diode, the organic electron transporting layer is not particularly limited, and any conventional organic electron transporting layer is suitably used in the present invention. Preferably, metal chelated oxinoids or chelates of oxine (i.e. Alq) may be used therein.

In the organic light emitting diode according to the present invention, preferably, the first conductive layer may be made of a metal or a metal compound with a work function larger than 4.0 eV.

In the organic light emitting diode according to the present invention, preferably, the second conductive layer may be made of a metal with a work function smaller than 4.0 eV.

In the organic light emitting diode according to the present invention, the substrate may be an insulating transparent substrate or an insulating opaque substrate. Preferably, a glass substrate, a semiconductor substrate, a plastic substrate or a ceramic substrate is used.

The method for manufacturing an organic light emitting diode according to the present invention includes following steps: (a) providing a substrate having a first conductive layer; (b) providing a precursor and polymerizing the precursor by plasma to form a fluorocarbon polymer layer or a fluorocarbon copolymer layer on the first conductive layer of the substrate; (c) forming an organic light emitting structure on the fluorocarbon polymer layer or the fluorocarbon copolymer layer; and (d) forming a second conductive layer on the organic light emitting structure.

In the method for manufacturing an organic light emitting diode according to the present invention, the substrate in step (a) can be a transparent substrate or an opaque substrate. Preferably, a glass substrate, a semiconductor substrate, a plastic substrate or a ceramic substrate is used.

In the method for manufacturing an organic light emitting diode according to the present invention, the first conductive layer in step (a) is not particularly limited, and may be an optically transparent conductive layer or an optically opaque conductive layer.

In the method for manufacturing an organic light emitting diode according to the present invention, preferably, the first conductive layer in step (a) is made of a metal or a metal compound with a work function larger than 4.0 eV, more preferably a metal compound with a work function larger than 4.0 eV, and most preferably Indium Tin Oxide (ITO).

In the method for manufacturing an organic light emitting diode according to the present invention, the fluorocarbon polymer layer in step (b) is not particularly limited, and preferably is a fluorizated poly xylylene layer.

In the method for manufacturing an organic light emitting diode according to the present invention, preferably, the precursor in step (b) may be a compound represented by the following formula (II) or a mixture containing the compound of the formula (II),

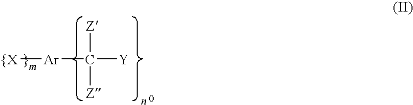

in which, n⁰ and m each independently are 0 or an integer larger than 0, and (n⁰+m) is 2 or an integer larger than 2 and not larger than the number of substitutable sites on Ar; Ar is a benzene moiety or a fluoro-benzene moiety; Z′ and Z″ are the same or different from each other and may be H, F, fluoroalkyl or fluorophenyl; X is —COOH, —I, —NR₂, —N⁺R₃, —SR or —SO₂R; and Y is —Cl, —Br, —I, —NR₂, —N⁺R₃, —SR, —SO₂R or —OR, wherein R is alkyl, fluoroalkyl, phenyl or fluorophenyl.

In the method for manufacturing an organic light emitting diode according to the present invention, the fluorocarbon polymer or the fluorocarbon copolymer layer in step (b) is preferably a hole injection layer.

In the method for manufacturing an organic light emitting diode according to the present invention, preferably, the fluorocarbon polymer or the fluorocarbon copolymer layer in step (b) is represented by the following formula (I),

(—CF₂—C₆X₄—CF₂—)ₙ (I)

wherein, X is H or F, and n is 2 or an integer larger than 2.

In the method for manufacturing an organic light emitting diode according to the present invention, preferably, the thickness of the fluorocarbon polymer layer or the fluorocarbon copolymer in step (b) ranges from 0.2 nm to 20 nm, and more preferably from 0.5 nm to 1 nm.

In the method for manufacturing an organic light emitting diode according to the present invention, preferably, the precursor in step (b) may be Br—CF₂—C₆H₄—CF₂—Br, Br—CF₂—C₆F₄—CF₂—Br or a mixture containing Br—CF₂—C₆H₄—CF₂—Br and Br—CF₂—C₆F₄—CF₂—Br.

In the method for manufacturing an organic light emitting diode according to the present invention, preferably, remote radio-frequency plasma with 13.6 MHz is used in step (b) to polymerize the precursor.

In the method for manufacturing an organic light emitting diode according to the present invention, preferably, remote plasma is employed in step (b) to polymerize the precursor.

In the method for manufacturing an organic light emitting diode according to the present invention, regarding step (b), the precursor may be polymerized by plasma at a pressure ranging from 0.1 mTorr to 600 mTorr.

In the method for manufacturing an organic light emitting diode according to the present invention, regarding step (b), the precursor is preferably provided at a flow rate ranging from 0.1 sccm to 1000 sccm, and more preferably from 1 sccm to 10 sccm.

In the method for manufacturing an organic light emitting diode according to the present invention, preferably, step (c) for forming the organic light emitting structure may include following steps: (c1) forming an organic hole transporting layer on the fluorocarbon polymer layer or the fluorocarbon copolymer layer; and (c2) forming an organic emissive layer or an organic electron transporting layer on the organic hole transporting layer.

In the method for manufacturing an organic light emitting diode according to the present invention, the second conductive layer in step (d) is not particularly limited, and preferably is a material with a work function smaller than 4.0 eV.

In the organic light emitting diode according to the present invention and the method for manufacturing the same, the organic light emitting structure may be a light emitting structure including a polymer material, such as a polymer light emitting diode.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of a conventional organic light emitting diode;

FIG. 2 is a cross-sectional view of another conventional organic light emitting diode;

FIG. 3 is a cross-sectional view of an organic light emitting diode according to Example 1 of the present invention;

FIG. 4 is a diagram of driving voltage versus current density according to an organic light emitting diode of the present invention;

FIG. 5 is a diagram of driving voltage versus brightness according to an organic light emitting diode of the present invention;

FIG. 6 is a diagram of driving time versus brightness according to Example 3 and Comparative Example of the present invention (---- for Example 3; . . . for Comparative Example; Lo: initial brightness; L: brightness after some driving time).

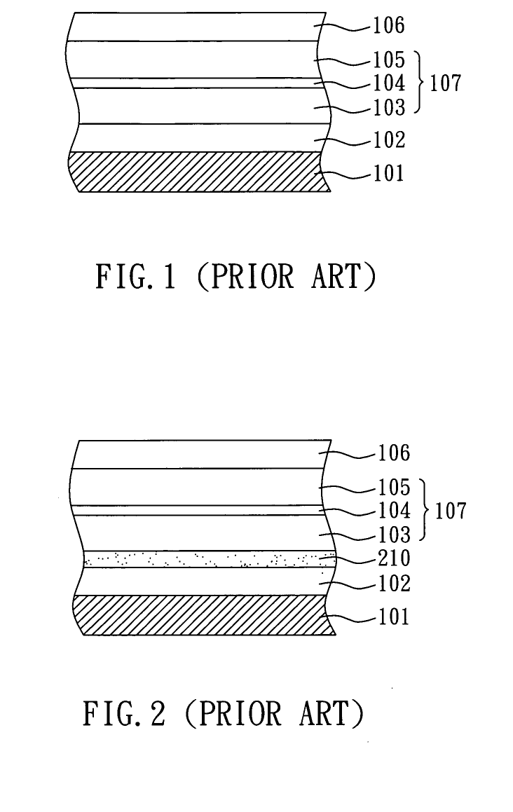

### DETAILED DESCRIPTION OF THE PREFERRED EMBODIMENT

### Example 1

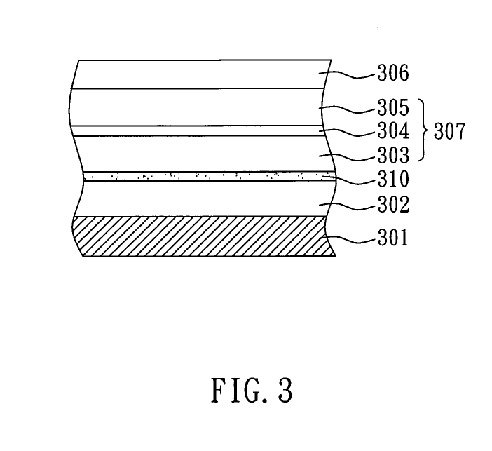

With reference to FIG. 3, there is shown a cross-sectional view of an organic light emitting diode according to the present invention. The organic light emitting diode according to the present invention includes: a substrate 301, a first conductive layer 302, a fluorizated poly xylylene layer 310, an organic light emitting structure 307 and a second conductive layer 306.

In the present embodiment, the substrate 301 is made of an insulating material, and the first conductive layer 302 is disposed on the substrate 301 to function as an anode of the organic light emitting diode and may be made of Indium Tin Oxide (ITO).

The fluorizated poly xylylene layer 310 is disposed on the first conductive layer 302, and may be a polymer layer or a copolymer layer represented by the following formula (I),

(—CF₂—C₆X₄—CF₂—)ₙ (I)

in which, X is H or F, and n is 2 or an integer larger than 2.

In the present embodiment, the fluorizated poly xylylene layer 310 is made of a polymer material of (—CF₂—C₆H₄—CF₂—)ₙ, or (—CF₂—C₆F₄—CF₂—)ₙ structure mainly consisting of carbon, hydrogen and fluorine elements. As the fluorizated poly xylylene layer 310, it is necessary to have sufficient thickness for overlapping the first conductive layer 302 overall. In the present embodiment, its thickness is 30 nm.

An organic light emitting structure 307 is formed on the fluorizated poly xylylene layer 310, which includes an organic hole transporting layer 303, an organic emissive layer 304 and an organic electron transporting layer 305. In the present embodiment, the organic hole transporting layer 303 is disposed on the fluorizated poly xylylene layer 310, and its material is 4,4′-bis-N-(1-naphthyl)-N-phenylaminokbi-phenyl (NPB). Herein, the thickness of the organic hole transporting layer 303 is 50 nm. The organic emissive layer 304 and the organic electron transporting layer 305 are disposed on the organic hole transporting layer 303 in sequence, and made of tri(8-quinolinolate-N1,08)-aluminum (Alq). Herein, the organic emissive layer 304 and the organic electron transporting layer 305 each have the thickness of 70 nm.

A second conductive layer 306 is formed on the organic light emitting structure 307. In the present embodiment, the second conductive layer 306 functions as a cathode of the organic light emitting diode, and is made of LiF/Al composite material with a thickness of 0.5 nm/200 nm.

Hereafter, the method for manufacturing an organic light emitting diode according to the present embodiment will be described in detail.

A substrate having a first conductive layer is first provided. In the present embodiment, the substrate 301 is a glass substrate, and the first conductive layer 302 is made of ITO, which is formed on the surface of the glass substrate by sputtering. Next, the glass substrate on which ITO is formed is washed with a commercial cleaning agent in an ultrasonic cleaner, and then washed with deionized water, acetone and isopropyl alcohol in sequence, followed by O₂ plasma treatment for 10 minutes.

Subsequently, the substrate is put into a chamber with a remote radical generator (such as a chamber in which radio-frequency remote plasma is provided), and a precursor is provided in the chamber to perform plasma polymerization so as to form a fluorizated poly xylylene layer 310 (or a copolymer layer containing fluoro-polyxylylene) on the first conductive layer 302 of the substrate 301,

In the present embodiment, the precursor is Br—CF₂—C₆H₄—CF₂—Br, Br—CF₂—C₆F₄—CF₂—Br or a mixture containing Br—CF₂—C₆H₄—CF₂—Br and Br—CF₂—C₆F₄—CF₂—Br. Herein, an output electric power of 13.6 MHz is applied on an electrode of the chamber to generate plasma in the chamber, and the plasma polymerization is performed in the chamber at 350 mTorr and 10 W so as to deposit a fluorizated poly xylylene layer 310 on the first conductive layer 302 of the substrate 301. The plasma polymerization is carried out at a temperature in a range of about 20° C. to 100° C. Practically, the temperature depends on operating parameters, such as power and deposition time. The polymer layer (i.e. the fluorizated poly xylylene layer) may be subjected to annealing in various conditions, other radiation treatments (such as ion implanting) or additional O₂, N₂ or H₂ plasma treatment.

In the present embodiment, the free radical generator is equipped far from the substrate. Herein, RF plasma is mainly localized in the free radical generator to ensure that the plasma parameters of RF plasma do not affect ion energy and the concentration of prepolymer. Accordingly, the impact energy of ions in the sheath area that pass through the glow plasma area) to the substrate can be reduced so as to form a fluorizated poly xylylene layer 301 with low roughness and excellent adhesion.

After the formation of the above-mentioned fluorizated poly xylylene layer 301 is accomplished, an organic light emitting structure is formed on the fluorizated poly xylylene layer. In the present embodiment, NPB of 50 nm thicknesses is first deposited on the fluorizated poly xylylene layer 310 as an organic hole transporting layer 303 by thermal evaporation, and then Alq is deposited on NPB as an organic emissive layer 304 and an organic electron transporting layer 305 by thermal evaporation. That is, in the present embodiment, the materials of the organic emissive layer 304 and the organic electron transporting layer 305 are Alq.

Subsequently, a second conductive layer 306 is formed on the above-mentioned organic light emitting structure 307 so as to accomplish the organic light emitting diode of present embodiment. In the present embodiment, the second conductive layer 306 is formed by depositing LiF/Al of 0.5 nm/200 nm thicknesses on the Alq layer through evaporation.

### Example 2

The structure and manufacturing method of the organic light emitting diode according to the present embodiment are the same as those described in Example 1, except that the thickness of the fluorizated poly xylylene layer is 15 nm.

### Example 3

The structure and manufacturing method of the organic light emitting diode according to the present embodiment are the same as those described in Example 1, except that the thickness of the fluorizated poly xylylene layer is 1 nm.

In the above-mentioned examples, the substrate 301 is a glass substrate, but not limited thereto. Any insulating substrate is suitably used in the present invention, and may be an optically transparent substrate or an optically opaque substrate. If light is extracted from the side of the substrate 301, the substrate 301 must have required optical transmittance. However, if light of the organic light emitting diode utilized is extracted from the second conductive layer 306, the substrate 301 can be made of opaque materials. Thereby, in the case, the substrate can be, for example, an opaque semiconductor or a ceramic substrate. Of course, in the case of using an opaque substrate, the second conductive layer must be transparent.

For the same reason, in the case of light being extracted from the side of the substrate 301, the first conductive layer 302 must have required optical transmittance. For example, ITO can be used as the first conductive layer 302. However, if light of the organic light emitting diode is extracted from the second conductive layer 306, the transmittance of the first conductive layer 302 is not critical. In such case, any suitable material can be used in the first conductive layer 302. For example, a metal or a metal compound with a work function larger than 4.0 eV can be used as the first conductive layer 302.

### Comparative Example

The structure and manufacturing method of the organic light emitting diode according to the comparative example are the same as those described in Example 1, except that no fluorizated poly xylylene layer is located on the first conductive layer. That is, the organic hole transporting layer directly contacts to the first conductive layer.

Hereafter, the test results of optical properties and electrical properties according to the above examples and comparative example will be described in detail, and the advantages of the present invention will be thoroughly explained.

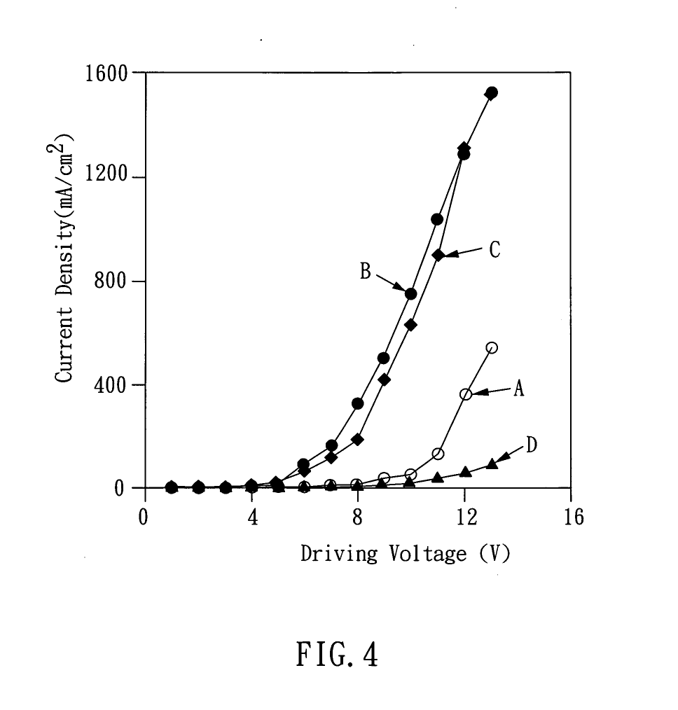

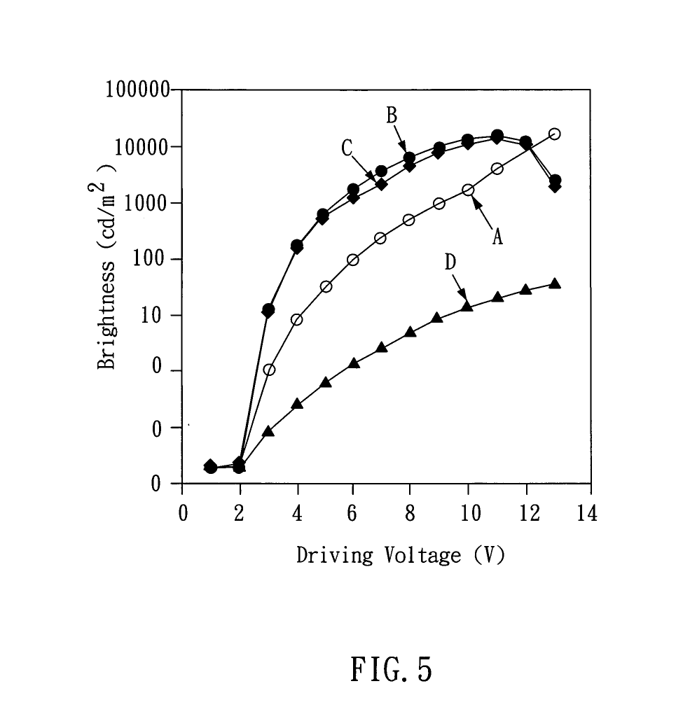

Please refer to FIGS. 4 and 5. FIG. 4 shows a diagram of driving voltage vs. current density according to Examples 1-3 and Comparative Example. FIG. 5 shows a diagram of driving voltage vs. brightness according to Examples 1-3 and Comparative Example. In FIGS. 4 and 5, the curve A represents Comparative Example, the curve B represents Example 3, the curve C represents Example 2, and the curve D represents Example 1.

In FIG. 4, the minimum current density appears in the curve D (i.e. Example 1, in which the thickness of the fluorizated poly xylylene layer is 30 nm). Thereby, it can be known that the fluorizated poly xylylene layer has very low conductivity and approximates an insulator. When the thickness of the fluorizated poly xylylene layer is reduced, as shown in the curves B (i.e. Example 2) and C (i.e. Example 1), the current density of the organic light emitting diode is significantly enhanced and surpasses the curve A (i.e. Comparative Example). That is, in the curves B (i.e. Example 2) and C (i.e. Example 1), for the same current density, a lower driving voltage is required. From the experimental results, it can be confirmed that the characteristics of the organic light emitting diode can be significantly improved by suitably modifying the properties of the fluorizated poly xylylene layer.

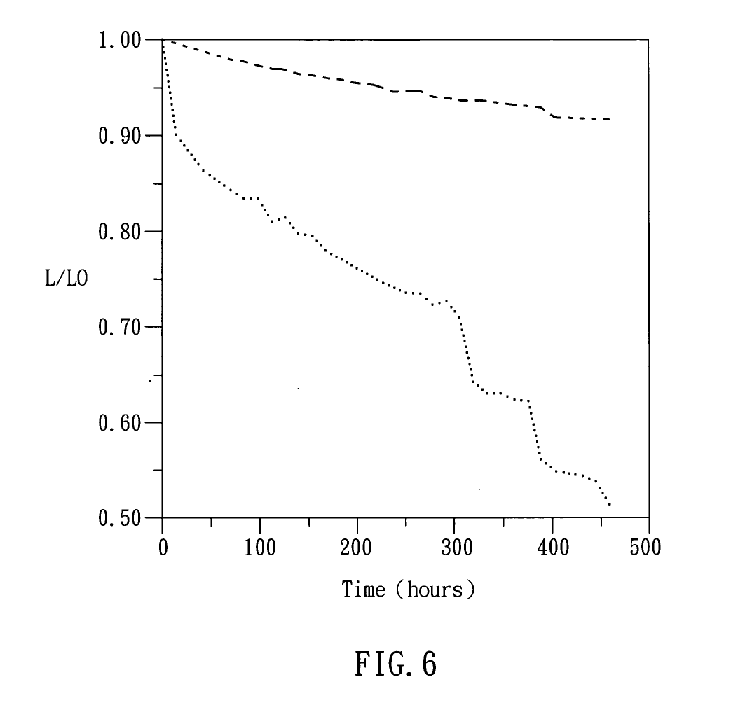

FIG. 5 shows that the brightness of the curves B (i.e. Example 2) and C (i.e. Example 1) is larger than that of the curve A (i.e. Comparative Example) at a driving voltage in a range of 0-10V, and even exceeds 10000 cd/m² at a higher voltage. FIG. 6 shows operating stability of diodes according to Example 3 and Comparative Example. The diode is driven with a high current density of 125 mA/cm² after package After 458 hours, the brightness of the diode (L) according to Comparative Example decays to about 51.0% based on the initial brightness (Lo). However, the brightness of the diode having the fluorizated poly xylylene layer (L) still remains 91.6% based on the initial brightness (Lo) after 458 hours. The result shows that the fluorizated poly xylylene layer deposited on ITO can significantly improve the operating stability of the diode. From the experimental results, it can be confirmed that the fluorizated poly xylylene layer of the organic light emitting diode plays a critical role in the emission mechanism. The optical and electrical properties of the organic light emitting diode can be significantly improved by applying the fluorizated poly xylylene layer.

The above experimental results prove that the application of the fluorizated poly xylylene layer in the organic light emitting diode can significantly improve the efficiency in hole injection so as to substantially enhance the current density of the organic light emitting diode. Accordingly, the present invention can achieve enhanced brightness, reduced driving voltage and improved operating stability.

Although the present invention has been explained in relation to its preferred embodiment, it is to be understood that many other possible modifications and variations can be made without departing from the scope of the invention as hereinafter claimed.

What is claimed is:

1. An organic light emitting diode, comprising:
a substrate;
a first conductive layer, disposed on a surface of the substrate;
a fluorocarbon polymer layer or a fluorocarbon copolymer layer, disposed on the first conductive layer;
an organic light emitting structure, disposed on the fluorocarbon polymer layer of the fluorocarbon copolymer layer; and
a second conductive layer, disposed on the organic light emitting structure.

2. The organic light emitting diode as claimed in claim 1, wherein the fluorocarbon polymer layer is a fluorizated poly xylylene layer.

3. The organic light emitting diode as claimed in claim 1, wherein the fluorocarbon polymer layer or the fluorocarbon copolymer layer is represented by the following formula (I),
(—CF₂—C₆X₄—CF₂—)ₙ (I)
wherein, X is H or F, and n is 2 or an integer larger than 2.

4. The organic light emitting diode as claimed in claim 1, wherein the substrate is a transparent substrate or an opaque substrate.

5. The organic light emitting diode as claimed in claim 1, wherein the thickness of the fluorocarbon polymer layer or the fluorocarbon copolymer layer ranges from 0.2 nm to 20 nm.

6. The organic light emitting diode as claimed in claim 1, wherein the organic light emitting structure comprises:
an organic hole transporting layer, formed on the fluorocarbon polymer layer or the fluorocarbon copolymer layer; and
an organic electron transporting layer, formed underneath the second conductive layer.

7. The organic light emitting diode as claimed in claim 6, further comprising an organic emissive layer disposed between the organic hole transporting layer and the organic electron transporting layer.

8. The organic light emitting diode as claimed in claim 6, wherein the organic hole transporting layer is made of aromatic tertiary amine.

9. The organic light emitting diode as claimed in claim 6, wherein the organic electron transporting layer is made of metal chelated oxinoids.

10. The organic light emitting diode as claimed in claim 1, wherein the first conductive layer is made of a metal or a metal compound with a work function larger than 4.0 eV.

11. The organic light emitting diode as claimed in claim 1, wherein the second conductive layer is made of a metal with a work function smaller than 4.0 eV.

12. The organic light emitting diode as claimed in claim 1, wherein the substrate is an insulating transparent substrate or an insulating opaque substrate.

13. A method for manufacturing an organic light emitting diode, comprising following steps:
(a) providing a substrate having a first conductive layer;
(b) providing a precursor and polymerizing the precursor by plasma to form a fluorocarbon polymer layer or a fluorocarbon copolymer layer on the first conductive layer of the substrate;
(c) forming an organic light emitting structure on the fluorocarbon polymer layer or the fluorocarbon copolymer layer; and
(d) forming a second conductive layer on the organic light emitting structure.

14. The method as claimed in claim 13, wherein substrate in step (a) is an insulating transparent substrate or an insulating opaque substrate.

15. The method as claimed in claim 13, wherein the first conductive layer in step (a) is an optically transparent conductive layer or an optically opaque conductive layer.

16. The method as claimed in claim 13, wherein the first conductive layer in step (a) is made of a metal or a metal compound with a work function larger than 4.0 eV.

17. The method as claimed in claim 13, wherein the fluorocarbon polymer layer in step (b) is a fluorizated poly xylylene layer.

18. The method as claimed in claim 13, wherein the precursor in step (b) may be a compound represented by the following formula (II) or a mixture containing the compound of the formula (II), 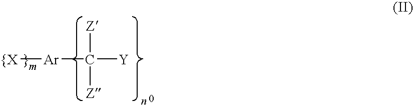
wherein, n⁰ and m each independently are 0 or an integer larger than 0, and (n⁰+m) is 2 or an integer larger than 2 and not larger than the number of substitutable sites on Ar;
Ar is a benzene moiety or a fluoro-benzene moiety;
Z′ and Z″ are the same or different from each other, being H, F, fluoroalkyl or fluorophenyl;
X is —COOH, —I, —NR₂, —N⁺R₃, —SR or —SO₂R; and
Y is —Cl, —Br, —I, —NR₂, —N⁺R₃, —SR, —SO₂R or —OR, wherein R is alkyl, fluoroalkyl, phenyl or fluorophenyl.

19. The method as claimed in claim 12, wherein the fluorocarbon polymer or the fluorocarbon copolymer layer in step (b) is a hole injection layer of the organic light emitting diode.

20. The method as claimed in claim 13, wherein the fluorocarbon polymer or the fluorocarbon copolymer layer in step (b) is represented by the following formula (I),
(—CF₂—C₆X₄—CF₂—)ₙ (I)
wherein, X is H or F, and n is 2 or an integer larger than 2.

21. The method as claimed in claim 13, wherein the thickness of the fluorocarbon polymer layer or the fluorocarbon copolymer in step (b) ranges from 0.2 nm to 20 nm.

22. The method as claimed in claim 13, wherein the precursor in step (b) is Br—CF₂—C₆H₄—CF₂—Br, Br—CF₂—C₆F₄—CF₂—Br or a mixture containing Br—CF₂—C₆H₄—CF₂—Br and Br—CF₂—C₆F₄—CF₂—Br.

23. The method as claimed in claim 13, wherein step (b) for polymerizing the precursor is performed by remote radio-frequency plasma with 13.6 MHz.

24. The method as claimed in claim 13, wherein step (b) for polymerizing the precursor is performed by remote plasma.

25. The method as claimed in claim 13, wherein step (b) for polymerizing the precursor is performed at a pressure ranging from 0.1 mTorr to 600 mTorr.

26. The method as claimed in claim 13, wherein the precursor in step (b) is provided at a flow rate ranging from 0.1 sccm to 1000 sccm.

27. The method as claimed in claim 26, wherein the precursor in step (b) is provided at a flow rate ranging from 1 sccm to 10 sccm.

28. The method as claimed in claim 13, wherein step (c) for forming the organic light emitting structure comprises following steps:
(c1) forming an organic hole transporting layer on the fluorocarbon polymer layer or the fluorocarbon copolymer layer; and
(c2) forming an organic emissive layer or an organic electron transporting layer on the organic hole transporting layer.

29. The method as claimed in claim 13, wherein the second conductive layer in step (d) has a work function smaller than 4.0 eV.
